(19) United States
(12) Patent Application Publication
(10) Pub. No.: US 2002/0044486 A1
(43) Pub. Date: Apr. 18, 2002

(54) IC card with different page sizes to increase endurance

(76) Inventors: Cheng-Sheng Chan, Hsinchu (TW); Po-Yuan Chen, Hsinchu (TW); Tien-Yu Pan, Taipei (TW)

Correspondence Address: BIRCH STEWART KOLASCH & BIRCH, PO BOX 747, FALLS CHURCH, VA, 22040-0747, US

(21) Appl. No.: 09/814,934

(22) Filed: Mar. 23, 2001

(30) Foreign Application Priority Data
Oct. 16, 2000 (TW) 89121553

(51) Int. Cl. G11C 11/34; G11C 16/04

(52) U.S. Cl. 365/185.33; 365/185.12

(57) ABSTRACT

An IC card of flash memory according to the present invention comprises an array of flash memory. The array has a plurality of pages having flash memory cells erased simultaneously. The pages comprise a relative-large page and a relative-small page. The number of the flash memory cells in the relative-large page is larger than that in the relative-small page. Seldom-change data codes, longer data codes and programs are stored into the relative-large pages. On the other hand, shorter data codes and frequently-changed data codes are stored into the relative-small pages. A better reliability can be achieved according to the present invention.

### BACKGROUND OF THE INVENTION

1. Field of the Invention

The present invention relates to a flash memory and a relevant semiconductor IC (integrated circuit) card system. In particular, the present invention relates to a flash memory with different page sizes, and its relevant application.

2. Description of the Related Art

Semiconductor IC card has been broadly utilized in daily life. Some of its applications are prepaid cards, IC cash cards, ID (identification) cards, and memory cards for digital cameras, etc. These applications issue at least three requirements for IC cards. The first one is preservation of the data stored, which can't be lost when the power is shut down. The second one is storage volume, which should be as large as possible to store the increasing data information. The third one is reliability, which means the endurance of read-and-write (R/W) cycling. An IC card should not damaged after a predetermined R/W cycle times.

To match the above requirements, IC card usually employs EEPROMs (electrically erasable and programmable read only memory) or flash memories (flash, in short) as its main memory device. The major different characteristic between EEPROM and flash is the number of memory cells erased at a time. Generally, the size erased once for EEPROM is 1 byte, and the one for flash is one page or one sector, which may contains hundreds or thousands of bytes. EEPROM has a good reliability, as high as 10⁴ to 10⁶ cycling times, to meet the market requirements, however, its disadvantages includes larger silicon chip area and higher cost. Each memory cell of EEPROM has two transistors; one acts as a selector, and the other acts as a storage unit. Increasing the storage capacity of an IC card of EEPROM usually confronts the difficulty in cost controlling and card assembling.

In comparison with EEPROM, flash sacrifices the flexibility of erasing size for the advantage of a smaller silicon chip area. On average, each memory cell of flash has one transistor. Therefore, small silicon chip area and low cost can be achieved. However, limited by the circuit architecture, the read-and-write operation of an IC card of flash may induce a lower reliability, especially when the size of each data for storage is much less than the size of a page.

When specific data, for example, is going to be stored in an empty region of a targeted page where pre-stored data must be preserved, three steps as followed must be executed step-by-step. (1) Read the pre-stored data in the targeted page to make a copy in other memories. In other words, duplicate the pre-stored data in other memories. (2) Erase all the data in the targeted page. (3) Write the copy and the specific data into the targeted page. These three steps are called as read-erase-write cycle. That is, in the targeted page, the memory cells for the pre-stored data, which intuitively should not experience any read-erase-write cycle, experience one time of read-erase-write cycle while writing information into the targeted pages. Specially, when seldom-changed data and frequently-changed data are located in a page, the memory cells for the seldom-changed data will suffer from many times of read-erase-write cycle due to the changes of the frequently-changed data. Therefore, even though the endurance of a single flash memory cell is equivalent to that of a single EEPROM memory cell, the reliability for an IC card of flash will be much worse than that for an IC card of EEPROM.

### SUMMARY OF THE INVENTION

An object of the present invention is to improve the reliability of an IC card.

One aspect of the present invention provides an IC card of flash memory comprising an array of flash memory. The array has a plurality of pages having flash memory cells erased simultaneously. The pages comprise a relative-large page and a relative-small page. The number of the flash memory cells in the relative-large page is larger than that in the relative-small page.

Another aspect of the present invention provides an IC card system comprising an array of flash memory, a memory controller and an input/output (I/O) interface. The array has a plurality of pages. Each page has flash memory cells erased simultaneously. The pages comprise a relative-large page and a relative-small page. The number of the flash memory cells in the relative-large page is larger than that in the relative-small page. The memory controller is used for allocating flash memories to store received information. The input/output (I/O) interface responses for accessing an external card reader.

Another aspect of the present invention provides a method for storing an instruction into an array of flash memory in an IC card. The array has a plurality of pages. Each page has flash memory cells erased simultaneously. The pages comprise a relative-large page and a relative-small page. The number of the flash memory cells in the relative-large page is larger than that in the relative-small page. The method comprise the following steps: (1) allocating, when the instruction is a data code and meets a first criterion, the relative-large page to store the instruction; and (2) allocating, when the instruction is a data code and meets a second criterion, the relative-large page stores the instruction.

Employing the IC card of the present invention, seldom-change data codes, longer data codes and programs are stored into the relative-large pages. On the other hand, shorter data codes and frequently-changed data codes are stored into the relative-small pages.

The present invention provides an even read-write cycle endurance for each page, thereby inducing a more efficient result. The IC card according to the present invention has better reliability.

### BRIEF DESCRIPTION OF THE DRAWINGS

The present invention can be more fully understood by reading the subsequent detailed description in conjunction with the examples and references made to the accompanying drawings, wherein:

FIG. 1 shows an IC memory card system implemented with a different page size flash memory according to the present invention;

FIG. 2 shows a flow diagram illustrating one kind implementation of a flash memory allocation scheme;

FIG. 3 shows a block diagram of an IC card with microprocessor according to the present invention; and

FIG. 4 shows multi-application card operating system structure of the chip card, which can dynamically download application programs into the IC card.

### DETAILED DESCRIPTION OF THE PREFERRED EMBODIMENT

The essence of the present invention is that, the array of flash memory of an IC card has small pages and large pages, where the words, “small” or “large”, are relative descriptions of the number of flash cells in a page. Employing the IC memory card of the present invention, seldom-changed data codes, longer data codes and programs are stored into the large pages. On the other hand, shorter data codes and frequently-changed data codes are stored into the small pages.

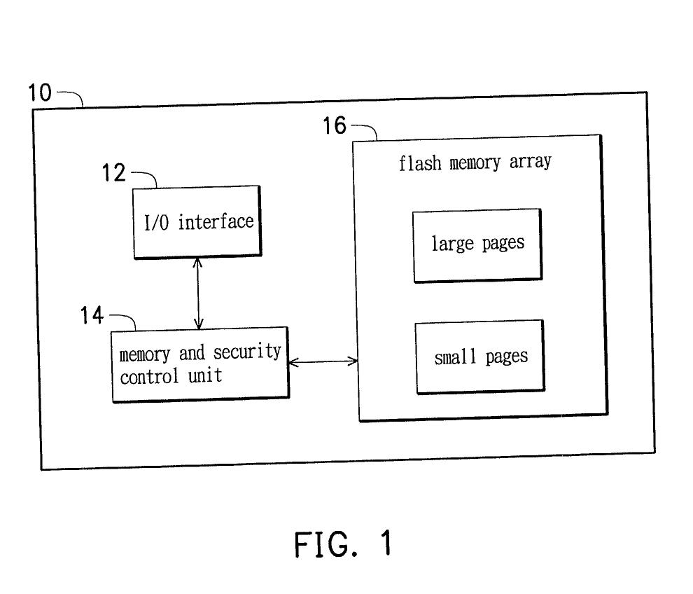

FIG. 1 shows an IC memory card system implemented with a different page size flash memory according to the present invention. Flash memories in an IC memory card 10 are placed to form a flash memory array 16 that comprises large pages and small pages. As known in the art, a page means a group of flash memory cells always being erased simultaneously. Memory and security control unit 14 responds for setting the operation condition of the flash memory array 16 and accessing the flash cells in the flash memory array 16. Input/output (I/O) interface 12 responses for the communication between the IC memory card 10 and a connected external apparatus, such as a card reader.

IC memory card 10 can be used to store data or programs. A datum consists of data codes. A program consists of instructions, which generally includes command codes and data codes.

The major concept of the present invention is that, data codes with shorter code lengths or being frequently changed are allocated (or stored) to small pages, and data codes with longer code lengths, being seldom changed or having a lower reliability issue are allocated (or stored) to large pages. Programs or Command codes, those that usually have a lower updating or writing frequency, are allocated (or stored) to large pages.

Code lengths of data codes are easily determined by counting the bytes of each data code. The changing frequency of data codes may depend on the attributes of the data codes. For example, assuming a data code is a personal ID, which should be attached to the user of the IC memory card for a long time, such that the data code should be allocated to large pages. On the other hand, assume a data code is a bank deposit, which is frequently changed by expenses or gains, such that the data code should be allocated to short pages.

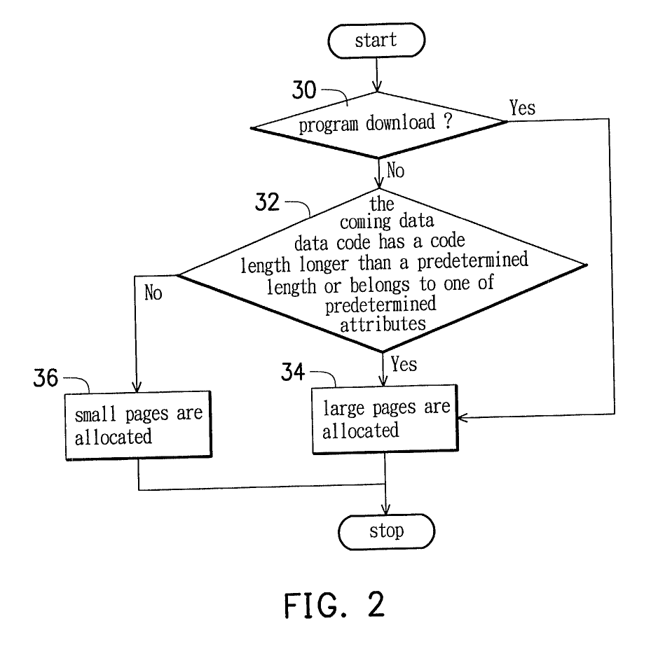

FIG. 2 shows a flow diagram illustrating one kind of implementation of a flash memory allocation scheme. The operating system controls all information written to flash memories. If a program download is found (yes for symbol 30), large pages are allocated to store that program (34). If a program download is not found (no for symbol 30), the incoming information is a datum. If the incoming data code has a code length longer than a predetermined number of bytes or belongs to one of predetermined attributes (yes for symbol 32), large pages are allocated to store that incoming data code (34). Otherwise (no of symbol 32), small pages are allocated to store that coming data code (34).

The read-write cycle endurance CT_{page} of a page can be simply expressed by the following equation (1):

CT_{page}α CT_{cell}/EF_{page}, (1)

where CT_{cell} denotes the read-write cycle endurance of a single flash cell and EF_{page} denotes the average frequency of erasing while writing information into the page. EF_{page} can be approximately expressed by the following equation (2):

EF_{page}α PS_{page}/DS_{info} (2)

where PS_{page} is page size denoting the total number of the flash cells in the page and DS_{info} denotes an averaged data size of each information stored in the page.

According to the present invention, longer data codes are allocated to large pages and shorter data codes are allocated to small pages. Therefore, the average frequencies of erasing, which are in proportion to PS_{page}/DS_{info}, for small pages will be very close to those for large pages if the line or criterion between longer data codes and shorter data codes is properly selected. In other words, the average frequencies of erasing for all pages are almost even. Therefore, each page, no matter its size is large or small, has an even read-write cycle endurance.

In contrast, the page sizes of an IC card in prior art are all even. Furthermore, data or programs are randomly allocated to a flash memory array in the prior art. Occasionally, if shorter data codes and longer data codes respectively crowd in a 1^{st} page and a 2^{nd} page having the same page size, the 1^{st} page will have a lower endurance than the 2^{nd} page according to the above analysis. An IC card fails if one memory cell inside it fails. That means the IC card fails at the moment the 1^{st} page wears out while the 2^{nd} page is still very healthy. It induces an inefficient result. In stead, the present invention provides an even read-write cycle endurance for each page, thereby inducing a more efficient result. Therefore the IC card according to the present invention has better reliability.

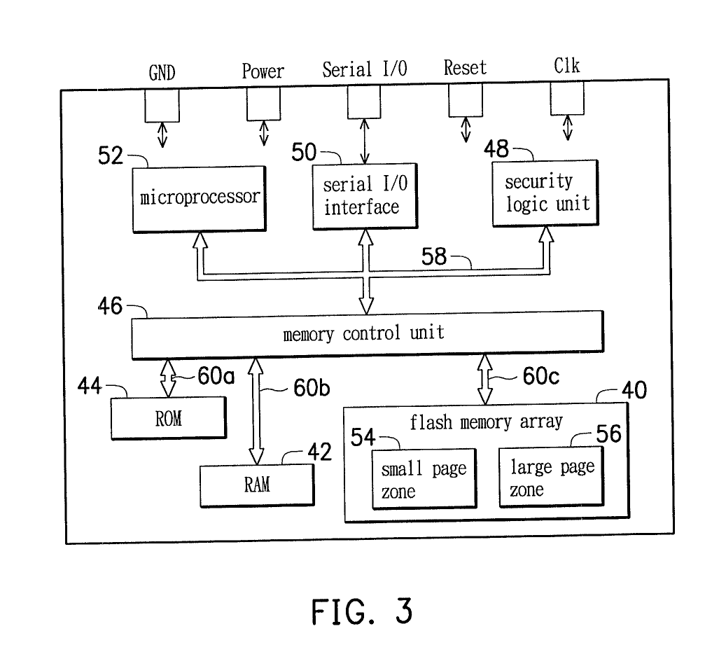

FIG. 3 shows a block diagram of a microprocessor chip card system according to the present invention. A microprocessor chip card system according the present invention has a flash memory array 40, a memory control unit 46, a serial I/O interface 50, a microprocessor 52, a security logic unit 48, a ROM 44 and a RAM 42. The flash memory array 40 has small pages, incorporated as a small page zone 54, and large pages, incorporated as a large page zone 56.

Through the system bus 58, Microprocessor 52 can access the serial I/O interface 50, security logic unit 48 and the memory control unit 46. The security logic unit 48 is used to avoid allowing the information in this microprocessor chip card system from being accessed by any unauthorized person.

Microprocessor 52 can access ROM 44, RAM 42 or the flash memory array 40 by the memory control unit 46 and the relative memory buss 60a, 60b and 60c. Generally, the operation system (OS) for controlling the operation of this microprocessor chip card system is stored in ROM 44 and any temporary information generated by the CPU is stored in RAM 42.

The flash memory array 40 can be used for storing portable information. Large page zone 56 can be allocated for storing application programs, longer data codes or frequently-changed data codes. Small page zone 54 can be allocated for storing shorter data codes or seldom-changed data codes. Such criteria for determining the allocation of information can be pr-built into the OS.

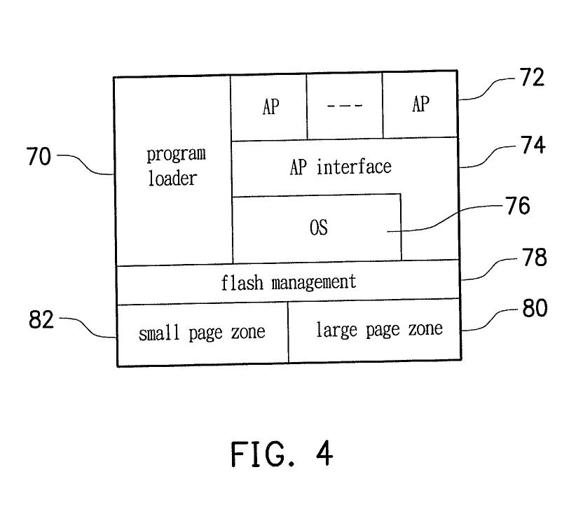

FIG. 4 shows multi-application card operating system structure of a chip card, which can dynamically download application programs into the IC card. Program loader 70 means the function that downloads an application program and AP 72 means an application program that can be downloaded into an IC card. By the assistance of the application interface 74, the program loader 70 and APs 72 are connected to OS 76 to access the large page zone 80 and the small page zone 82 through the flash management 78. Depending on the implementation method, the program loader 70 and the application interface 74 can directly access the flash management 78, as shown in FIG. 4. The flash management 78 allocates the large page zone 80 or the small page zone 82 to meet the need from the OS 76, the application interface 74 or the program loader 70 according to the criteria of the present invention.

Finally, while the invention has been described by way of examples and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

what is claimed is:

1. An IC memory card of flash memory, comprising an array of flash memory, the array having a plurality of pages, each page having flash memory cells erased simultaneously, the pages comprising a relative-large page and a relative-small page, wherein the number of the flash memory cells in the relative-large page is larger than that in the relative-small page.

2. The IC memory card as claimed in claim 1, wherein the IC card further comprises a memory controller for allocating flash memory to store received information.

3. The IC memory card as claimed in claim 1, wherein the IC card further has an input/output (I/O) interface for accessing an external system.

4. The IC memory card as claimed in claim 1, wherein the relative-large page is allocated for storing a plurality of long-length data codes, the relative-small page is allocated for storing a plurality of short-length data codes, and the long-length data codes have a code length longer than the short-length data codes.

5. An IC card system, comprising:
an array of flash memory, the array having a plurality of pages, each page having flash memory cells erased simultaneously, the pages comprising a relative-large page and a relative-small page, wherein the number of the flash memory cells in the relative-large page is larger than that in the relative-small page;
a memory controller for allocating flash memories to store received information; and
an input/output (I/O) interface for accessing to an external card reader.

6. The IC card system as claimed in claim 5, wherein the relative-large page is allocated for storing a plurality of long-length data codes, the relative-small page is allocated for storing a plurality of short-length data codes, and the long-length data codes have a code length longer than the short-length data codes.

7. The IC card system as claimed in claim 6, wherein the relative-large page is further allocated for storing a plurality of command codes.

8. The IC card system as claimed in claim 5, wherein the IC card system further has a microprocessor for controlling the memory controller the I/O interface.

9. The IC card system as claimed in claim 8, wherein the IC card system further comprises a read only memory (ROM) for storing an operation system (OS), and the microprocessor operates according to the OS to allocate the relative-large page for storing long-length data codes and to allocate the relative-small page for storing short-length data codes.

10. The IC card system as claimed in claim 9, wherein, according to the OS, the microprocessor allocates the relative-large page for storing command codes.

11. The IC card system as claimed in claim 8, wherein the IC card system further comprises a RAM (random access memory) for temporarily storing information from the microprocessor.

12. The IC card system as claimed in claim 8, wherein the IC card system further comprises a security logic circuit to avoid unauthorized access.

13. A method for storing an instruction into an array of flash memory in an IC card, the array having a plurality of pages, each page having flash memory cells erased simultaneously, the pages comprising a relative-large page and a relative-small page, wherein the number of the flash memory cells in the relative-large page is larger than that in the relative-small page, the method comprising:
allocating, when the instruction is a data code and meets a first criterion, the relative-large page to store the instruction; and
allocating, when the instruction is a data code and meets a second criterion, the relative-large page to store the instruction.

14. The method as claimed in claim 13, wherein the first criterion is that the data code has a code length longer than a predetermined code length and the second criterion is that the data code has a code length shorter than the predetermined code length.

15.The method as claimed in claim 13, wherein the first criterion is that the data code matches one of predetermined types and the second criterion is that the data code doesn't match any one of the predetermined types.

16. The method as claimed in claim 13, wherein the method further comprises a step of allocating, when the instruction is a command, the relative-large page to store the instruction.
